(19) United States
(12) Patent Application Publication
(10) Pub. No.: US 2024/0266420 A1
(43) Pub. Date: Aug. 8, 2024

(54) SEMICONDUCTOR DEVICE

(71) Applicant: Nippon Telegraph and Telephone Corporation, Tokyo (JP)

(72) Inventors: Yuki Yoshiya, Tokyo (JP); Takuya Hoshi, Tokyo (JP); Hiroki Sugiyama, Tokyo (JP); Hideaki Matsuzaki, Tokyo (JP)

(21) Appl. No.: 18/561,355

(22) PCT Filed: Jun. 2, 2021
(86) PCT No.: PCT/JP2021/020936

§ 371 Date: Nov. 16, 2023

(51) Int. Cl. H01L 29/66; H01L 29/20; H01L 29/207; H01L 29/778

(52) U.S. Cl. CPC H01L 29/66462; H01L 29/2003; H01L 29/207; H01L 29/7786

(57) ABSTRACT

This semiconductor device includes a substrate, a buffer layer formed on the substrate, a first semiconductor layer formed on the buffer layer, a second semiconductor layer formed on the first semiconductor layer, and a channel layer and a barrier layer formed on the second semiconductor layer. The substrate includes a nitride semiconductor doped with impurities to have semi-insulating properties or high resistance, the buffer layer includes GaN, the first semiconductor layer includes GaN doped with an acceptor, and the second semiconductor layer includes AlGaN.

### CROSS-REFERENCE TO RELATED APPLICATIONS

This patent application is a national phase entry of PCT Application No. PCT/JP2021/020936, filed on Jun. 2, 2021, which application is hereby incorporated herein by reference.

### TECHNICAL FIELD

The present invention relates to a semiconductor device utilizing a nitride semiconductor.

### BACKGROUND

A hetero-junction field effect transistor (HFET) or a high electron mobility transistor (HEMT) is a transistor which performs an ON/OFF operation by changing carrier density of a channel layer through an electric field generated by a gate voltage.

When a nitride semiconductor is used, for example, with an AlGaN layer and a GaN layer being laminated, a two-dimensional electron gas (2DEG) formed by collecting electrons at an interface is used as a channel so as to compensate for a difference in magnitude of polarization between these layers. In the HEMT having the nitride semiconductor of a general Ga polarity, a gate electrode is formed on an AlGaN layer of about several nm to several tens of nm, and the 2DEG concentration of the interface between AlGaN and GaN is controlled.

When high frequency applications of the HEMT with the nitride semiconductor are considered, it is important to confine carriers in a thin region at the interface between AlGaN and GaN and to remove other leakage paths. With such a configuration, a response operation to the voltage applied to a gate electrode is accelerated, and a stable operation can be realized.

As a substrate used for forming an element such as a transistor using the nitride semiconductor as described above, a GaN substrate is superior in terms of epitaxial growth and the like. However, since the GaN substrate which is not subjected to intentional doping indicates an n-type conductivity type, impurity doping is performed in order to make the GaN substrate semi-insulating or high resistance. Generally, Fe and Zn are used as an impurity for making the GaN substrate semi-insulating or high resistance.

An advantage of the semi-insulating (or high resistance) GaN substrate in a high frequency device is that leakage paths can be reduced. When a device is laminated on a thin buffer by using the semi-insulating (or high resistance) GaN substrate, leakage into the substrate and buffer leakage can be reduced.

### CITATION LIST

### Non Patent Literature

Non Patent Literature 1: T. Ishiguro et al., “New Model of Fe Diffusion in High Resistant Fe-Doped Buffer Layer for GaN High-Electro-Mobility Transistor”, Japanese Journal of Applied Physics, vol. 52, 08JB17, 2013.
Non Patent Literature 2: Y. Ni et al., “Low-leakage current and high-breakdown voltage GaN-on-Si (111) System with an AlGaN impurity blocking layer”, Journal of Materials Science: Materials in Electronics, vol. 27, pp. 5158-5163, 2016.

### SUMMARY

### Technical Problem

By the way, in the GaN substrate having the semi-insulating or high resistance, there is a problem in which impurities contained in the substrate diffuse into the nitride semiconductor layer epitaxially grown on the substrate and adversely affect the device. For example, Non Patent Literature 1 indicates that a doped Fe diffuses over several hundreds nm into GaN on the Fe-doped layer. Since Zn and Fe of impurities of the substrate act as a trap of electrons in a layer epitaxially grown on the substrate, when the impurities diffuse into the vicinity of the device structure, carriers of a channel are trapped and high-speed operation of the device is limited.

As one method for preventing impurities from diffusing into the device layer, it is conceivable to grow a GaN buffer thicker. The concentration of the impurity diffused from the substrate in the epitaxial growth layer decreases as the epitaxial growth layer becomes thicker, with the interface between the substrate and the epitaxial growth layer being a peak. Therefore, if the buffer layer is sufficiently thick, the impurity concentration in the epitaxial growth layer as the device structure can be suppressed low. However, since the impurity concentration remains over several hundreds of nm in the GaN buffer layer, the thickness of the GaN buffer has to be increased in the above-mentioned method, but this is uneconomical. And this method cannot utilize the effect of buffer leak reduction which is the advantage of utilizing the GaN substrate having the semi-insulating property or high resistance.

As another method for preventing the diffusion of impurities into the device layer, it is conceivable to insert an AlGaN layer as an impurity diffusion prevention layer. According to Non Patent Literature 2, diffusion of Si is suppressed by interposing the AlGaN layer. Based on the same principle, it is considered that the AlGaN layer can function as a diffusion prevention layer for Fe and Zn as well. In this case, the thickness of the AlGaN layer may be about several tens to a hundred and several tens of nm, and the diffusion of impurities from the substrate can be suppressed by a thinner thickness as compared with the method of thickening the buffer layer. However, in this method, since the 2DEG is formed at the interface between the inserted AlGaN layer and the underlying GaN buffer, this 2DEG becomes a problem as a new leakage path.

As described above, the conventional art has the problem in which the diffusion of impurities, which are introduced to make the substrate on which the nitride semiconductor is formed have semi-insulating properties or high resistance, into the device of the nitride semiconductor formed on the substrate for a nitride semiconductor is not easy to be suppressed without affecting the device characteristics of the device formed on the substrate.

Embodiments of the present invention have been made to solve the above-mentioned problem, the object of which is to suppress the diffusion of impurities introduced to make the substrate, on which the nitride semiconductor is formed, have semi-insulating properties or high resistance, without affecting the device characteristics of the device formed on the substrate.

### Solution to Problem

A semiconductor device according to embodiments of the present invention includes a substrate having a nitride semiconductor doped with an impurity to have semi-insulating properties or high resistance, a buffer layer formed on the substrate and having GaN, a first semiconductor layer formed on the buffer layer and having GaN doped with an acceptor, a second semiconductor layer formed on the first semiconductor layer and having AlGaN, and a channel layer and a barrier layer formed on the second semiconductor layer and having a nitride semiconductor.

### Advantageous Effects of Embodiments of the Invention

As described above, according to embodiments of the present invention, since the first semiconductor layer having GaN doped with the acceptor is provided on the buffer layer having GaN, diffusion of impurities, which are introduced to make the substrate, on which the nitride semiconductor is formed, have semi-insulating properties or high resistance, can be suppressed without affecting the device characteristics of the device formed on the substrate.

### BRIEF DESCRIPTION OF THE DRAWINGS

FIG. 1A is a view showing a partial configuration of a semiconductor device according to an embodiment of the present invention.

FIG. 1B is a band diagram showing a band structure calculated in a structure excluding a first semiconductor layer of the semiconductor device according to an embodiment of the present invention.

FIG. 1C is a band diagram showing a band structure calculated in a structure of the semiconductor device according to an embodiment of the present invention.

FIG. 2 is a band diagram showing a band structure calculated in a structure of the semiconductor device according to an embodiment of the present invention.

### DETAILED DESCRIPTION OF ILLUSTRATIVE EMBODIMENTS

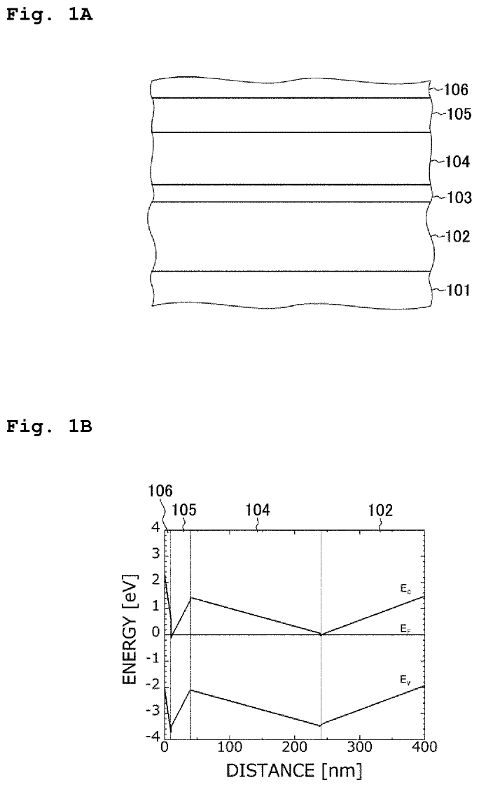

Hereinafter, the semiconductor device according to an embodiment of the present invention will now be described with reference to FIG. 1A. This semiconductor device includes a substrate 101, a buffer layer 102 formed on the substrate 101, a first semiconductor layer 103 formed on the buffer layer 102, a second semiconductor layer 104 formed on the first semiconductor layer 103, and a channel layer 105 and a barrier layer 106 formed on the second semiconductor layer. This semiconductor device includes the channel layer 105 having a nitride semiconductor and the barrier layer 106 as a part of a device structure and is a field effect type transistor (HEMT) having, for example, a gate electrode and source/drain electrodes (not shown) provided on the barrier layer 106 and using a 2DEG formed in the vicinity of their interfaces as a channel.

The substrate 101 includes a nitride semiconductor doped with impurities to have semi-insulating properties or high resistance. The substrate 101 can include GaN doped with Zn or Fe, for example. This is a generally used semi-insulating GaN substrate or a high resistance GaN substrate. Since GaN becomes an n-type in a manufacturing method not doped with impurities, the above-mentioned impurities are doped for semi-insulation (or high resistance). The buffer layer 102 includes GaN and is formed on the substrate 101 in contact therewith, for example. The thickness of the buffer layer 102 can be 300 nm or less.

The first semiconductor layer 103 includes GaN doped with an acceptor and is formed on the buffer layer 102 in contact therewith, for example. The acceptor of the first semiconductor layer 103 can be at least one of Mg, Fe, and Zn. And, in this case, the acceptor concentration can be 1×10¹⁷ cm⁻³ to 1×10¹⁹ cm⁻³. And, in this case, the thickness of the first semiconductor layer 103 can be 50 nm or less.

And, the acceptor of the first semiconductor layer 103 can be C, and the concentration of the acceptor can be 1×10¹⁸ cm⁻³ or more. In this case, the thickness of the first semiconductor layer 103 can be 10 nm or less.

The second semiconductor layer 104 includes AlGaN and is formed on the first semiconductor layer 103 in contact therewith, for example. The second semiconductor layer 104 includes AlₓGa₁₋ₓN (0<x≤0.1), for example, and the thickness can be 200 nm or less.

The semiconductor device according to the embodiment has a construction in which the first semiconductor layer 103 having GaN doped with the acceptor and the second semiconductor layer 104 having AlGaN are inserted between the buffer layer 102 that is an initial growth layer on the substrate 101 and the channel layer 105 which forms the device structure. This can provide an effect as described below.

First, the diffusion of impurities from the substrate 101 can be effectively suppressed while thinning the entire layer of each nitride semiconductor epitaxially grown on the substrate 101. The concentration of impurities diffused into the channel layer 105 can be reduced without thickening the buffer layer 102 due to the second semiconductor layer 104.

Second, the 2DEG formed on the interfaces, in the case where the second semiconductor layer 104 and the buffer layer 102 are formed in contact with each other, can be suppressed. With doping the acceptor to only a relatively thin region in the vicinity of these interfaces to form the first semiconductor layer 103, the band is raised to prevent the formation of the 2DEG. Since the first semiconductor layer 103 formed by doping the acceptor has a thickness of 50 nm or less and the above-mentioned effect can be obtained, the leakage path can be efficiently removed without largely increasing the entire thickness.

The following will be described in more detail. Since the substrate 101 having GaN becomes an n-type in a manufacturing method not doped with impurities, the impurities are doped for semi-insulation (or high resistance). As the impurity to be doped, for example, Zn or Fe is assumed. In the following description, a case where the substrate 101 includes semi-insulating GaN doped with Zn will be described.

It has been found that the doped impurity diffuses into the epitaxially grown layer when crystal growth is performed on the substrate 101. If the impurity diffuses into the vicinity of the device layer, it functions as a trap for carriers and affects the device characteristics. Since the diffusion of the impurity from the substrate 101 ranges from 200 to 300 nm, it is uneconomical because the thickness of the buffer layer needs to grow to 300 nm or more in order to block the influence of the impurity on the device by making the buffer layer 102 thick. Further, with making the buffer layer 102 thick, impurities can be prevented, but a new factor that the device performance is suppressed by the buffer leakage and the like occurs.

In contrast to this, by inserting the second semiconductor layer 104 having AlGaN between the buffer layer 102 and the channel layer 105, the diffusion of impurity is prevented while keeping the buffer layer 102 thin to 300 nm or less. Further, the second semiconductor layer 104 also functions as a back barrier layer from the viewpoint of a device structure of an upper layer.

Since the second semiconductor layer 104 is required to have a thickness of about several tens nm to several hundreds nm in order to prevent diffusion of impurities, considering a critical film thickness accompanying lattice mismatch with the underlying buffer layer 102, the Al composition cannot be increased. In order to grow an AlGaN layer of several tens nm to several hundreds nm on a GaN layer while avoiding the occurrence of cracks, it is desirable to keep the Al composition at 0.1 or less. For this reason, the second semiconductor layer 104 has, for example, the Al composition of 0.05 and a thickness of 200 nm.

Under this condition, a band structure calculated in a structure excluding the first semiconductor layer 103 is shown in FIG. 1B. The barrier layer 106 has the Al composition of 0.4 and the thickness of 10 nm. The channel layer 105 has a thickness of 30 nm. The Al composition and thickness of the barrier layer 106 and the thickness of the channel layer 105 are not limited to these values, and almost the same results can be obtained under the conditions of the barrier layer and the channel layer used in a general HEMT.

As shown in FIG. 1B, a conduction band E_{C} is lower than a Fermi level E_{F} at the interface between the second semiconductor layer 104 and the buffer layer 102, and carriers of several % of carrier density at the interface between the barrier layer 106 and the channel layer 105 are generated. High-concentration carriers generated in layers other than the channel layer 105 can become leakage paths during the operation of the HEMT and are not desirable.

In contrast to this, in embodiments of the present invention, as described above, the first semiconductor layer 103 doped with the impurity is inserted between the second semiconductor layer 104 and the buffer layer 102 so as to prevent the formation of carriers. In order to prevent the generation of electrons, it is only to dope the first semiconductor layer 103 with an impurity serving as an acceptor and, for example, Mg, Fe, Zn, C and the like are assumed for the acceptor. For example, Mg can be used as the acceptor. When Mg is used as the acceptor, doping of a high concentration may cause a new problem such as introduction of defects and/or inversion of the polarity of GaN. Therefore, when Mg is used as the acceptor, it is difficult to dope a high concentration such as 10²⁰ cm⁻³.

Further, as the Mg concentration is increased, holes exceeding the 2DEG concentration formed under the second semiconductor layer 104 are formed in the first semiconductor layer 103 having several nm thickness and become new leakage paths, so that a Mg concentration of about 10¹⁸ cm⁻³ is desirable.

On the other hand, when the Mg concentration is lowered, a sufficient 2DEG suppressing effect cannot be obtained in the thin first semiconductor layer 103, and the purpose (object) of intending to thin the buffer layer 102 is not satisfied. In order to obtain an effect with a thickness of about 50 nm, a Mg concentration of 10¹⁷ cm⁻³ or more is required for the first semiconductor layer 103. For example, the doping amount of Mg in the first semiconductor layer 103 can be set to 1×10¹⁸ cm⁻³. In this doping amount, a result that the first semiconductor layer 103 has a thickness of 30 nm, for example, is shown in FIG. 1C.

As shown in FIG. 1C, a band between the second semiconductor layer 104 and the buffer layer 102 is raised by the first semiconductor layer 103, and a conduction band E_{C} is located at a position higher than a Fermi level E_{F}, thereby the carrier density among them is reduced to a level that the influence on the device characteristics can be negligible. From this calculation result, it can be understood that the formation of 2DEG under the second semiconductor layer 104 can be effectively suppressed by the thin first semiconductor layer 103, with setting the doping amount to 1×10¹⁸ cm⁻³ and the thickness to 30 nm in the first semiconductor layer 103.

When the first semiconductor layer 103 using Mg as the acceptor is increased in thickness, the 2DEG is suppressed though a new leakage path occurs because the hole density is increased, so that it is not desirable to make the thickness of the first semiconductor layer 103 100 nm or more.

By the way, the effect of the first semiconductor layer 103 does not depend on the thickness of the underlying buffer layer 102. Further, since the first semiconductor layer 103 and the buffer layer 102 are homo-epitaxial growth (lattice matching) on the substrate 101, unlike the case of hetero-epitaxial growth, it is possible to reduce the thickness to about several tens nm. Thinning the buffer layer 102 on the substrate 101 leads to prevention of formation of an unnecessary leakage path, and reduction of device cost can be expected.

Next, a case in which the acceptor of the first semiconductor layer 103 is C will be described. When the acceptor of the first semiconductor layer 103 is set to C, it is possible to relax the limit of the doping amount taken into consideration when Mg is doped. Therefore, the same effect can be obtained by the thin first semiconductor layer 103 because of doping the acceptor as C with a higher concentration.

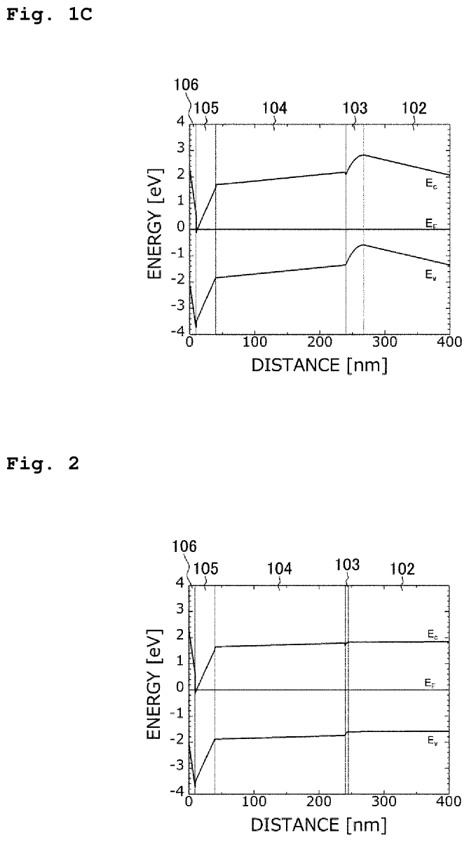

FIG. 2 shows a result of calculation in which the conditions of layers other than the first semiconductor layer 103 is set the same as described above, and the C concentration of the first semiconductor layer 103 is set to 5×10¹⁸ cm⁻³ and the thickness is set to 5 nm.

Although the first semiconductor layer 103 is thin, a band between the second semiconductor layer 104 and the buffer layer 102 is raised as shown in FIG. 2, and the carrier density between them decreases to a level at which the influence on the device characteristics can be negligible.

In this way, when C (carbon) is used as the acceptor, unlike the case where the acceptor is Mg, Fe, Zn or the like, since the formation of holes does not occur in spite of making the first semiconductor layer 103 thick, this thickness is not much limited (upper limit). However, in the case in which homo-epitaxial growth is assumed on the substrate 101, with thinning the total thickness of the buffer layer 102 and the first semiconductor layer 103, it is expected to prevent formation of an unnecessary leak path and to reduce the device cost. Unlike the case of Mg, in the case of C doping that is not limited to high concentration doping, more thinning of the first semiconductor layer 103 can be realized and the effect of thinning the buffer layer 102 becomes larger.

As described above, according to embodiments of the present invention, since the first semiconductor layer having GaN doped with the acceptor is provided on the buffer layer having GaN, diffusion of impurities, which are introduced for making a substrate having the nitride semiconductor have semi-insulating properties or high resistance, can be suppressed without affecting the device characteristics of the device formed on the substrate.

By the way, it is clear that embodiments of the present invention are not limited to the embodiments described above, and many modifications and combinations can be implemented by those skilled in the art within the technical concept of the present invention.

### REFERENCE SIGNS LIST

101 Substrate
102 Buffer layer
103 First semiconductor layer
104 Second semiconductor layer
105 Channel layer
106 Barrier layer

1.-5. (canceled)

6. A semiconductor device comprising:
a substrate comprising a first nitride semiconductor doped with impurities to have semi-insulating properties or high resistance;
a buffer layer on the substrate, the buffer layer comprising GaN;
a first semiconductor layer on the buffer layer, the first semiconductor layer comprising GaN doped with an acceptor;
a second semiconductor layer on the first semiconductor layer, the second semiconductor layer comprising AlGaN; and
a channel layer and a barrier layer on the second semiconductor layer, the channel layer and the barrier layer each comprising a second nitride semiconductor.

7. The semiconductor device according to claim 6, wherein the substrate comprises GaN doped with Zn or Fe.

8. The semiconductor device according to claim 7, wherein:
the buffer layer has a thickness of 300 nm or less; and
the second semiconductor layer comprises AlₓGa₁₋ₓN (0<x≤0.1) and has a thickness of 200 nm or less.

9. The semiconductor device according to claim 8, wherein:
the acceptor comprises Mg, Fe, or Zn;
a concentration of the acceptor is 1×10¹⁷ cm⁻³ to 1×10¹⁹ cm⁻³; and
the first semiconductor layer has a thickness of 50 nm or less.

10. The semiconductor device according to claim 8, wherein:
the acceptor comprises C;
a concentration of the acceptor is 1×10¹⁸ cm⁻³ or more; and
the first semiconductor layer has a thickness of 10 nm or less.

11. The semiconductor device according to claim 7, wherein:
the acceptor comprises Mg, Fe, or Zn;
a concentration of the acceptor is 1×10¹⁷ cm⁻³ to 1×10¹⁹ cm⁻³; and
the first semiconductor layer has a thickness of 50 nm or less.

12. The semiconductor device according to claim 7, wherein:
the acceptor comprises C;
a concentration of the acceptor is 1×10¹⁸ cm⁻³ or more; and
the first semiconductor layer has a thickness of 10 nm or less.

13. A method of forming a semiconductor device, the method comprising:
forming a buffer layer comprising GaN on a substrate, the substrate comprising a first nitride semiconductor doped with impurities to have semi-insulating properties or high resistance;
forming a first semiconductor layer on the buffer layer, the first semiconductor layer comprising GaN doped with an acceptor;
forming a second semiconductor layer on the first semiconductor layer, the second semiconductor layer comprising AlGaN; and
forming a channel layer and a barrier layer on the second semiconductor layer, the channel layer and the barrier layer each comprising a second nitride semiconductor.

14. The method according to claim 13, wherein the substrate comprises GaN doped with Zn or Fe.

15. The method according to claim 14, wherein:
the buffer layer has a thickness of 300 nm or less; and
the second semiconductor layer comprises AlₓGa₁₋ₓN (0<x≤0.1) and has a thickness of 200 nm or less.

16. The method according to claim 15, wherein:
the acceptor comprises Mg, Fe, or Zn;
a concentration of the acceptor is 1×10¹⁷ cm⁻³ to 1×10¹⁹ cm⁻³; and
the first semiconductor layer has a thickness of 50 nm or less.

17. The method according to claim 15, wherein:
the acceptor comprises C;
a concentration of the acceptor is 1×10¹⁸ cm⁻³ or more; and
the first semiconductor layer has a thickness of 10 nm or less.

18. The method according to claim 14, wherein:
the acceptor comprises Mg, Fe, or Zn;
a concentration of the acceptor is 1×10¹⁷ cm⁻³ to 1×10¹⁹ cm⁻³; and
the first semiconductor layer has a thickness of 50 nm or less.

19. The method according to claim 14, wherein:
the acceptor comprises C;
a concentration of the acceptor is 1×10¹⁸ cm⁻³ or more; and
the first semiconductor layer has a thickness of 10 nm or less.
